(19) United States
(12) Patent Application Publication
(10) Pub. No.: US 2001/0036725 A1
(43) Pub. Date: Nov. 1, 2001

(54) METHOD FOR FABRICATING A BOTTOM ANTI-REFLECTIVITY COATING LAYER

(76) Inventor: STEVEN CHANG, HSINCHU (TW)

Correspondence Address: J C PATENTS INC, 1340 REYNOLDS AVE, SUITE 114, IRVINE, CA, 92614

(21) Appl. No.: 09/335,633

(22) Filed: Jun. 18, 1999

(51) Int. Cl. H01L 21/4763; H01L 21/31; H01L 21/469; H01L 21/44

(52) U.S. Cl. 438/636; 438/785; 438/945; 438/669; 438/685

(57) ABSTRACT

A method of fabricating a bottom anti-reflectivity coating (BARC) layer. The method of the invention comprises performing a pre-bake process on a provided titanium nitride layer. Amine ions absorbed into the surface of the titanium nitride layer are thus removed by the high temperature of the pre-bake process. A BARC layer is formed on the titanium nitride layer. A bake step is performed to remove a solvent, which is used for coating the BARC layer. A photoresist layer is coated on the BARC layer. Then, a soft-bake step is performed to remove a solvent, which is used for coating the photoresist layer. A photomask with a pattern is provided over the photoresist layer. An exposure step is performed to transfer the pattern to the photoresist layer. A development step is performed to remove a part of the photoresist layer so that the pattern is shown within the photoresist layer. A hard-bake step is performed to minimize the solvent in the photoresist layer.

### BACKGROUND OF THE INVENTION

1.Field of the Invention

The invention relates in general to a method for fabricating an anti-reflectivity layer in a semiconductor device, and more particularly to a method of fabricating a bottom anti-reflectivity coating (BARC) layer.

2.Description of the Related Art

Many metal materials, such as gates of MOS transistors or wiring lines, are used for fabricating semiconductor devices. Polycide, comprising a doped polysilicon layer and silicide, is the major material of MOS transistor gates in the fabrication of semiconductor. Aluminum (Al), copper (Cu), and alloy comprising aluminum and copper are often used for fabricating the wiring lines. Photolithography and etching processes are performed to pattern the gate structure and the wiring lines. The reflection of the materials due to a high reflectivity index of the metal materials makes line width error. In order to reduce the reflection, a BARC layer is provided on the polycide or on the metal materials prior to the formation of a photoresist layer. Since the BRAC layer has a lower reflectivity index than the metal materials, the reflection off the metal materials can thus be reduced, and the line width error can be diminished.

A conventional method for forming wiring lines comprises forming a metal layer on a provided substrate. A titanium nitride layer as a barrier layer is formed on the metal layer. The fabrication of the titanium nitride layer comprises depositing a titanium layer on the metal layer and nitrogenizing the titanium layer in an atmosphere containing nitrogen (N₂) or ammonia (NH₃). The titanium nitride layer is thus formed. A BARC layer is coated on the titanium nitride layer. A photoresist material is provided on the BARC layer. Then, a pattern is defined within the photoresist material. The definition process comprises soft-bake, exposure, development, hard-bake and removal of a part of the photoresist material.

However, after removing a part of the photoresist layer, a little photoresist material, which is predetermined to be removed, remains on comers between the photoresist layer and the BARC layer as shown in FIG. 1.

In FIG. 1, a substrate 100 is provided. A titanium nitride layer 101 is formed on the substrate 100. A BARC layer 102 and a photoresist layer 104 are formed over the titanium nitride layer 101. The photoresist layer is an organic material. When a photolithography and etching is performed, light passes through a mask into the photoresist layer 104. The photoresist layer 104 reacts with the passing light so that the photoresist material converts into a compound with an acid group. The acid group can reacts with a base group so that the photoresist layer can be easily removed by basic solutions. A pattern on the mask is thus transferred to the photoresist layer 104.

However, few amine ions, which are used to form the titanium nitride layer 101, do remain on the surface of the titanium nitride layer 101. While performing the photolithography and etching process, the amine ions may diffuse through the BRAC layer and react with the acid group of the photoresist layer 104. The acid group is neutralized and is not removed by base solutions. The result of remaining photoresist material, which is predetermined to be removed, is called “footing”. This induces line width error in the photoresist layer 104.

### SUMMARY OF THE INVENTION

The invention provides a method of fabricating a BARC layer to resolve problems created by footing. The method of the invention comprises performing a pre-bake process on a provided titanium nitride layer. Amine ions absorbed on the surface of the titanium nitride layer are thus removed by the high temperature of the pre-bake process. A BRAC layer is formed on the titanium nitride layer. A bake step is performed to remove a solvent, which is used for coating the BARC layer. A photoresist layer is coated on the BARC layer. Then, a soft-bake step is performed to remove a solvent, which is used for coating the photoresist layer. A photomask with a pattern is provided over the photoresist layer. An exposure step is performed to transfer the pattern to the photoresist layer. A development step is performed to remove a part of the photoresist layer so that the pattern is shown within the photoresist layer. A hard-bake step is performed to minimize the solvent in the photoresist layer.

The pre-bake process further comprises baking the titanium nitride layer at a temperature of about 170-300 degrees Celsius to remove the amine ions on the surface of the titanium nitride layer, and then cooling the titanium nitride layer. Since the amine ions are removed before performing the photolithography process, no amine ion reacts with acid groups of the photoresist layer formed during exposure. After developing, sidewalls of the photoresist layer are completely vertical without “footing”.

### BRIEF DESCRIPTION OF THE DRAWINGS

Other objects, features, and advantages of the invention will become apparent from the following detailed description of the preferred but non-limiting embodiments. The description is made with reference to the accompanying drawings in which:

FIG. 1 is a schematic, cross-sectional view showing a footing effect resulting from a conventional photolithography process; and

FIGS. 2A to 2D are schematic, cross-sectional views showing the process steps of one preferred embodiment of a photolithography process.

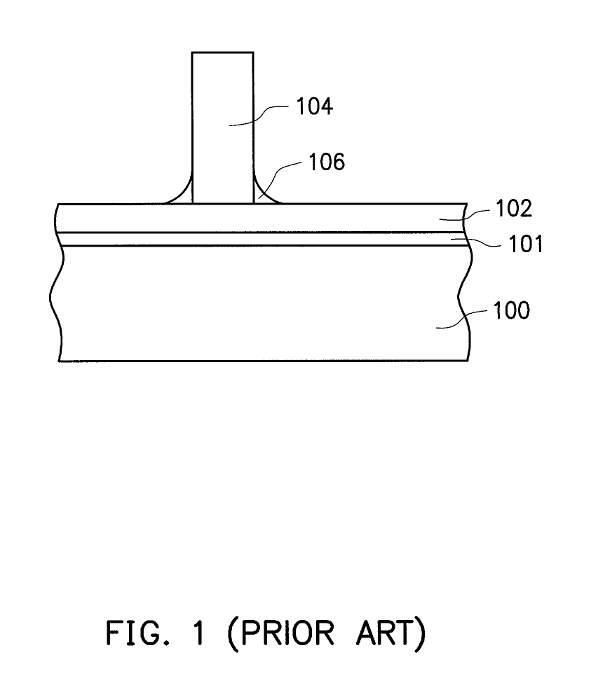

### DESCRIPTION OF THE PREFERRED EMBODIMENT

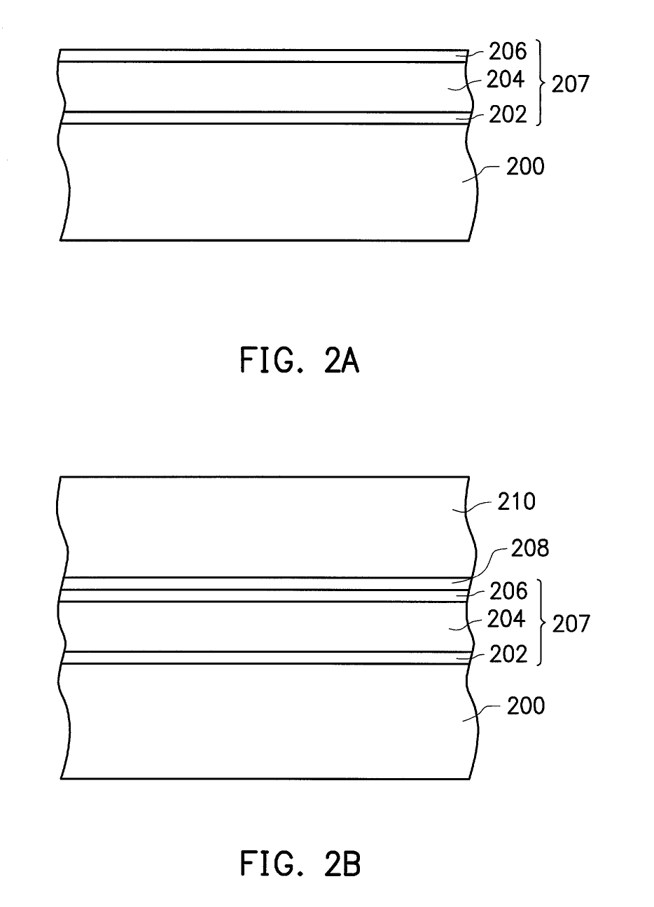

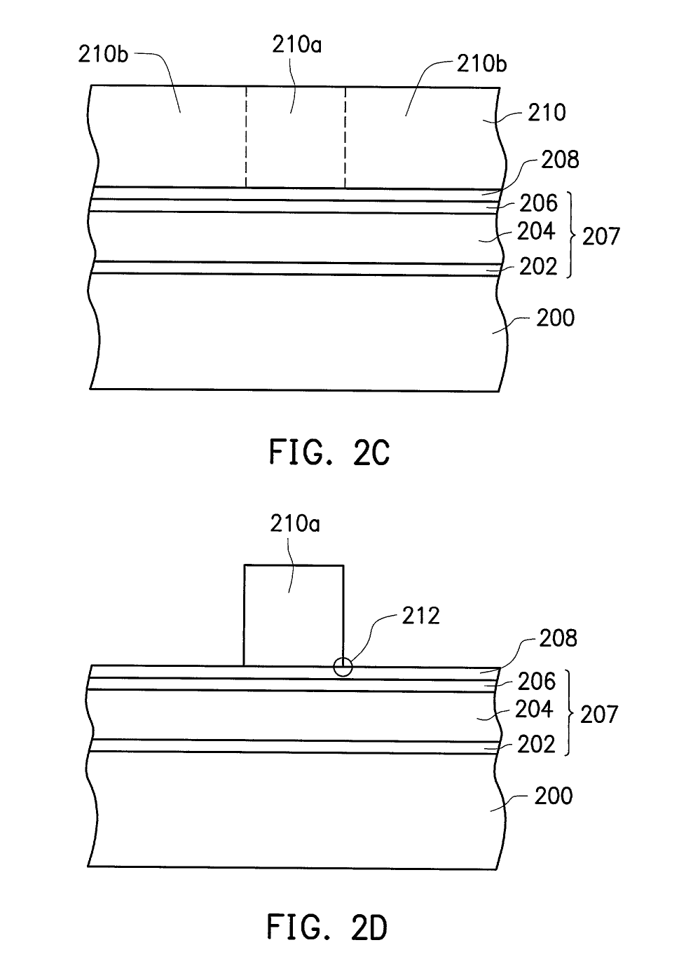

FIGS. 2A to 2D are schematic, cross-sectional views showing the process steps of one preferred embodiment of a photolithography process.

In FIG. 2A, a substrate 200 is provided. A conductive layer 207 is formed on the substrate 200. The conductive layer 207 may be a multi-layer structure. For example, the conductive layer 207 is a three-layer structure comprising a titanium layer 202, an aluminum copper alloy layer 204 and a titanium nitride layer 206. The titanium nitride layer 206 is formed by nitrogenizing a titanium layer (not shown) on the alloy layer 204. The nitridation for forming the titanium nitride layer 206 is performed in an atmosphere containing nitrogen (N₂) or ammonia (NH₃) at a high temperature.

A pre-bake process is performed on the titanium nitride layer 206. The pre-bake process further comprises two steps. One step is baking the titanium nitride layer 206 at a temperature of about 170-300 degrees Celsius. The baking step is performed for about 50-70 seconds. The other step is cooling the titanium nitride layer 206 to room temperature, which is about 23 degrees Celsius. The cooling step is performed for about 10-30 seconds.

In FIG. 2B, a BARC layer 208 is coated on the titanium nitride layer 20 after performing the pre-bake process. The BARC layer is about 990 Å thick. A bake step is performed on the BARC layer 208 at a temperature of about 120-200 degrees Celsius to remove a solvent, which is used for coating the BARC layer 208. A photoresist layer 210 is formed on the BARC layer 208. The photoresist layer 210 is about 9800 Å thick. A soft-bake step is performed to remove a solvent, which is used for coating with the photoresist layer 210. The BARC layer comprises an organic material, which has similar characteristics to those of the photoresist layer 210.

In FIG. 2C, a photomask (not shown) with a pattern is provided over the photoresist layer 210. A part of the photoresist layer 210 is exposed. An exposure step is performed to transfer the pattern to the photoresist layer 210. Light is provided and passes through the photomask into the exposed photoresist layer 210. The exposed photoresist layer 210 reacts with the passing light to convert into a compound 210b containing an acid group. The other photoresist layer 210a covered by the photomask does not react with the passing light.

In FIG. 2D, a developing reagent is used to develop the pattern of the photoresist layer 210. The exposed photoresist layer 210b is removed by the developing reagent. The other photoresist layer 21Oa remaining on the BARC layer 208 has vertical sidewalls, which have orthogonal corners 212 as shown in figure. After development, a hard-bake step is performed to minimize the solvent contained in the photoresist layer 210a.

It should be noted that the cooling step must be performed after baking the titanium nitride layer 206. If the cooling step is not performed, the adhesion between the BARC layer 208 and the titanium nitride layer 206 is reduced by stress between the BARC layer 208 and the titanium nitride layer 206.

The major feature of the invention is the performance of a pre-bake process on the titanium nitride layer before coating a BARC layer on the titanium nitride layer. Amine ions absorbed on the surface of the titanium nitride layer are removed by the pre-bake process, so that no amine ions diffuse through the BARC layer to react with acid groups of the exposed photoresist layer. After development, the remaining photoresist layer has vertical sidewalls without footing.

While the invention has been described by way of example and in terms of a preferred embodiment, it is to be understood that the invention is not limited thereto. To the contrary, it is intended to cover various modifications and similar arrangements and procedures, and the scope of the appended claims therefore should be accorded the broadest interpretation so as to encompass all such modifications and similar arrangements and procedures.

What is claimed is:

1. A method of fabricating a bottom anti-reflectivity coating layer, comprising the steps of:
providing a titanium nitride layer;
performing a pre-bake process on the titanium nitride layer;
forming a bottom anti-reflectivity coating layer on the titanium nitride layer; and
baking the bottom anti-reflectivity coating layer.

2. The method according to claim 1, wherein the pre-bake process further comprises steps of:
baking the titanium nitride layer at a high temperature of about 170-300 degrees Celsius; and
cooling the titanium nitride layer to room temperature.

3. The method according to claim 2, wherein the baking step is performed for about 50-70 seconds.

4. The method according to claim 2, wherein the cooling step is performed for about 10-30 seconds.

5. The method according to claim 1, wherein the titanium nitride layer is formed by nitridation.

6. The method according to claim 5, wherein a gas used for nitridation comprises nitrogen.

7. The method according to claim 5, wherein a gas used for nitridation comprises ammonia.

8. A photolithography process, comprising the steps of:
providing a conductive layer;
baking the conductive layer at a high temperature;
cooling the conductive layer;
coating a bottom anti-reflectivity coating layer on the conductive layer;
baking the bottom anti-reflectivity coating layer;
coating a photoresist layer on the bottom anti-reflectivity coating layer;
performing a soft-bake step on the photoresist layer;
patterning the photoresist layer to remove a part of the photoresist layer; and
performing a hard-bake step on the remaining photoresist layer.

9. The process according to claim 8, wherein the conductive layer further comprises a titanium nitride layer.

10. The process according to claim 8, wherein the high temperature for baking the conductive layer is about 170-300 degrees Celsius.

11. The process according to claim 8, wherein the cooling step is performed to cool the conductive layer to about 23 Degrees Celsius for about 10-30 seconds.
